(19) United States
(12) Patent Application Publication
(10) Pub. No.: US 2009/0209217 A1
(43) Pub. Date: Aug. 20, 2009

(54) Electronic Device, System, Chip and Method Enabling a Radio Signal Reception

(76) Inventors: Edmund Coersmeier, Bochum (DE); Martin Kosakowski, Bochum (DE); Stefan Mende, Recklinghausen (DE); Yuhuan Xu, Espoo (FI); Thomas Hinzmann, Viersen (DE); Jesper Hartig Larsen, Kastrup (DK)

Correspondence Address: WARE FRESSOLA VAN DER SLUYS & ADOLPHSON, LLP, BRADFORD GREEN, BUILDING 5, 755 MAIN STREET, P O BOX 224, MONROE, CT, 06468, US

(21) Appl. No.: 12/083,576

(22) PCT Filed: Oct. 14, 2005
(86) PCT No.: PCT/IB2005/003076

§ 371 Date: Feb. 5, 2009

(51) Int. Cl. H03D 5/00

(52) U.S. Cl. 455/142

(57) ABSTRACT

The invention relates to an electronic device comprising a headset connector adapted to connect a headset to the electronic device and an active amplifier circuit connected to the headset connector. The active amplifier circuit is adapted to amplify radio signals received by an antenna, which is connected to the electronic device via the headset connector. The invention relates equally to a chip comprising such an active amplifier circuit, to a system comprising the electronic device and to a corresponding method for receiving radio signals at such an electronic device.

### CROSS REFERENCE TO RELATED APPLICATIONS

This application is the U.S. National Stage of International Application Number PCT/IB05/003076 filed on Oct. 14, 2005 which was published in English on Apr. 19, 2007 under International Publication Number WO 2007/042855.

### FIELD OF THE INVENTION

The invention relates to an electronic device, to a system, to a chip and to a method enabling a radio signal reception.

### BACKGROUND OF THE INVENTION

It is known to enhance mobile communication devices with additional functions that are not directly related to mobile communications. One example for such an enhancement is an analog frequency modulation (FM)-radio receiver implemented in a mobile phone.

FM radio broadcasting uses frequencies in a range of 88 MHz to 108 MHz. The short wavelength of these frequencies allows using any of the connection lines of a headset connected to a mobile communication device as a passive antenna, from which the FM radio frequency signal can be filtered in the FM-radio receiver.

The current amplitude modulation (AM) radio broadcasting, in contrast, uses short wave, medium wave and long wave transmissions in an overall frequency range of 150 kHz to 30 MHz. It thus uses wavelengths that are large compared to ultra short waves or FM radio waves, respectively. As a consequence, AM-radio receivers typically require several meters of passive antenna wire for enabling a reception, which is not feasible with mobile phones or other handheld devices.

Enabling an AM-band reception in handheld devices is also of interest with regard to Digital Radio Mondiale (DRM). DRM is a digital broadcasting system that is defined in the ETSI standards. It provides digital voice, audio, text and image broadcasting and enables fully new services with a global coverage. DRM is designed to be used within the existing AM band. DRM broadcasting has been started in 2003, and in the long term DRM broadcasting will replace the complete analog signal broadcasting within the AM band. Thus, the problem described above for AM-radio reception occurs as well for DRM reception that is to be enabled in a handheld device.

For illustration, a DRM reception will be described in more detail with reference to FIGS. 1 to 4.

FIG. 1 is a diagram illustrating different spheres above the Earth's surface 10. More specifically, the atmosphere 11, which is closest to the Earth, is followed by the stratosphere 12 and the ionosphere 13. The ionosphere 13 itself is further composed of a D-layer at approximately 40 km to 90 km from the Earth's surface 10, an E-layer at approximately 90 km to 130 km from the Earth's surface 10 and an F1+F2 layer at approximately 130 km to 250 km from the Earth's surface 10. In addition, an AM-band transmitter 21 and an AM-band receiver 22 are depicted. AM-band wave propagation uses reflections at the ionosphere 13 and at the Earth's surface 10 for propagating globally around the word.

FIG. 2 is a diagram illustrating short wave propagations in the 3 MHz to 30 MHz band. The ground wave 25, that is, a direct propagation between a transmitter 21 and receivers 22, becomes more or less meaningless, as it may be blocked rather quickly by obstacles 23. Sky waves 26 are reflected to a large extend by the ionosphere 13 and can thus pass very long distances. Sky waves 26 may reach a receiver 22 directly after a reflection at the ionosphere 13, or after additional reflections, for instance at the Earth's surface 10 and the ionosphere 13. A dead zone caused by obstacles 23 might be considered.

FIG. 3 is a schematic block-diagram of an analog front-end of a homodyne DRM receiver. The depicted components may be integrated, for example, on a single receiver chip.

The DRM front-end comprises an antenna 300, which is connected via a preselection filter 301 and a capacitor 302 to the input of a low noise amplifier (LNA) with automatic gain control (AGC) 303. The output of the LNA 303 is connected on the one hand to an in-phase branch, comprising in this order a first downconversion mixer 310, a first adjustable amplifier 311, a first low pass filter 312, a second adjustable amplifier 313 and a first Delta-Sigma analog-to-digital converter (DS-ADC) 314. The output of the LNA 303 is connected on the other hand to a quadrature branch, comprising in this order a second downconversion mixer 320, a third adjustable amplifier 321, a second low pass filter 322, a fourth adjustable amplifier 323 and a second DS-ADC 324. Both the first and the second ADC 314, 315 are connected to a digital signal processor 330. The first and the third adjustable power amplifiers 311, 321 are controlled by the digital signal processor 330 via a respective DC-Offset Compensation component 315, 325.

In addition, an oscillator 304 provides a signal that is fed to a fractional-N phase-locked-loop (PLL) 305. The output of the PLL 305 is frequency divided by two by a frequency divider 306 and provided as an in-phase local oscillator signal (LO_I) to the first mixer 310 and as a quadrature local oscillator signal (LO_Q) to the second mixer 320.

When a signal is received via the antenna 300, it is band-pass filtered by the preselection filter 301 according to a desired frequency range and amplified by the LNA 303. The signal is then downconverted by the mixers 310, 320 to an analog in-phase baseband signal and an analog quadrature baseband signal using the local oscillator signal LO_I and the local oscillator signal LO_Q, respectively. The analog in-phase and quadrature baseband signals are amplified by amplifier 311, 321, low-pass filtered by low-pass filter 312, 322, further amplified by amplifier 313, 323 and converted into a digital baseband signal by ADC 314, 324 in the in-phase branch and in the quadrature branch, respectively. The resulting digital baseband signals BB_I and BB_Q are fed to the digital signal processor 330. The digital signal processor may perform a digital base band processing including a digital source decoding and de-framing, in order to provide digital signals that allow regain the analog audio signal.

The actual antenna 300 of the DRM front-end of FIG. 3 can be for example a quarter-wave vertical antenna 300, as presented in FIG. 4. The length of a quarter wave of current 410 and voltage 420 induced into the antenna 300, which corresponds to the length of the actual antenna 300, is denoted λ/4, while the length of a half wave of current 410 and voltage 420, which corresponds to the combined length of the actual antenna 300 and of the mirrored antenna 400 mirrored at the root point 401 of the actual antenna 301, is denoted λ/2. A is the wavelength of the carrier frequency of received radio signals. It is a disadvantage of this antenna 300 that it has to be very long, namely several meters long, in order to allow receiving DRM short wave signals.

AM-band reception with a shorter antenna can be realized by employing an active antenna. For use in mobile phones, however, conventional active antennas have significant disadvantages, namely a high weight, high prices or high voltage requirements, respectively.

### SUMMARY OF THE INVENTION

It is an object of the invention to enable a feasible reception of lower frequency radio signals, like AM-band signals, in mobile phones and other handheld devices.

An electronic device is proposed, which comprises a headset connector adapted to connect a headset to the electronic device. In addition, the electronic device comprises an active amplifier circuit connected to the headset connector. The active amplifier circuit is adapted to amplify radio signals received by an antenna, which is connected to the electronic device via the headset connector.

Moreover, a system is proposed, which comprises such an electronic device and an antenna connected to the electronic device via the headset connector.

Moreover, a chip for an electronic device is proposed, which comprises an input enabling a connection to a headset connector of the electronic device. The chip further comprises an active amplifier circuit connected to the input. The active amplifier circuit is adapted to amplify radio signals received by an antenna, which is connected to the electronic device via the headset connector.

Finally, a method for receiving radio signals at an electronic device is proposed. The method comprises receiving radio signals via an antenna, which is connected to the electronic device via a headset connector of the electronic device. The method further comprises amplifying the received radio signals with an active amplifier circuit.

The invention proceeds from the consideration that an active antenna enables a reduction of its physical dimension compared to a passive antenna. An active antenna comprises a passive part, namely the antenna element, and an active part, namely an active amplifier.

The effective height h_{eff} of an active antenna corresponds to the ratio of the output open-circuit voltage of the antenna amplifier Uₐ to the electrical field strength E:

$${h}_{eff} = \frac{{U}_{a}}{E}$$

The effective area A_{eff} of an active antenna corresponds to the ratio of the signal power at the amplifier output P_{a,out} to the radiation density Pₙ:

$${A}_{eff} = \frac{{P}_{a , out}}{{P}_{n}}$$

With an active antenna, the antenna signal can be coupled out high-ohmic, and the matching to the wave resistance, for instance a wave resistance 50Ω in the case of a coaxial cable, can be done at the output of the antenna amplifier. For passive antennas, a 50Ω matching to the wave resistance of coaxial cable has to be done in a passive way, which is a big drawback due to worse antenna properties and more signal attenuation, and since more current will be coupled out of the antenna element.

As conventional active antennas, which comprise both the passive and the active antenna element, are large and costly, it is proposed that an active amplifier circuit forming the active antenna element is coupled to a headset connector of an electronic device. As a result, a passive antenna element connected to the headset connector, for instance wires of a headset, can be combined with the active amplifier circuit to an active antenna.

It is an advantage of the invention that the active amplifier circuit enables a lower-frequency radio reception with a rather short antenna, which is thus usable for small electronic devices like mobile phones as well. It is moreover an advantage of the invention that it does not require a dedicated passive antenna element within the electronic device. As a result, the signal reception can be realized with low costs, for example by using a headset cable of a connected headset as an antenna.

The antenna reception efficiency of the active antenna should be high and the active amplifier circuit should provide a low noise input stage, which is high-omic and low capacitive to reduce the loading of the antenna. In an exemplary embodiment of the invention, the active amplifier circuit comprises one or more Junction-Field-Effect-Transistors (JFET) and/or one or more Metal-Oxide-Semiconductor-Field-Effect-Transistors (MOSFET) as active amplifier(s) for meeting these goals.

The capability of a semi-conductor based active amplifier circuit depends strongly on the employed semi-conductor technology, as low noise and linear active elements are needed.

It is an advantage of JFETs that they provide a good compromise between noise behavior and input capacitance. For JFETs, the 1/f noise behavior is negligible for frequencies higher than 1 kHz, whereas for MOSFETs, the 1/f noise behavior is relevant for frequencies up to 100 kHz. Normally, the implementation of JFETs is also a process option in most used semi-conductor technologies. The advantage of MOSFET transistors is their lower input capacitance and their availability in nearly every semi-conductor technology. Thus, in particular if JFETs are not available within the used technology, also MOSFETs can be used, but they are noisier and therefore will increase the overall circuit noise in the signal chain.

In an exemplary embodiment of the invention, the electronic device and/or the proposed chip further comprise at least one processing component for processing signals amplified by the active amplifier circuit. The at least one processing component may comprise any component of a known radio signal receiver, for instance the components of a conventional DRM receiver presented above with reference to FIG. 3, etc.

The at least one processing component may belong for instance to a radio receiver of the electronic device, which is adapted to process radio signals in a frequency range of 10 kHz to 30 MHz. The antenna for a mobile receiver for this frequency range has to be very small to fulfill the mobility aspect. An active vertical antenna of approximately one meter length would be sufficient to receive the full frequency range from 10 kHz to 30 MHz.

Such a radio receiver may be for example an AM-radio receiver and/or a DRM radio receiver. In the case of a DRM radio receiver, the relevant frequency range is limited to approximately 150 kHz to 30 MHz.

In one embodiment of the invention, the headset connector is adapted to connect a wire of at least one headset earspeaker to the active amplifier circuit, when a headset comprising at least one earspeaker is connected to the electronic device via the headset connector.

This embodiment is particularly suited for a DRM receiver. It is an advantage of DRM that the required signal-to-noise-ratio (SNR) for a stable reception is as low as 15 dB.

In other embodiment of the invention, the headset connector is adapted to connect a wire of a headset microphone to the active amplifier circuit, when a headset comprising a microphone is connected to the electronic device via the headset connector. In this case, a switch may be provided, which is adapted to disconnect wires of a microphone of a headset from a microphone interface, when a headset comprising a microphone is connected to the electronic device via the headset connector and radio signals are to be received.

It is to be understood that instead of a switch, another separation component could be used. For example, a low-pass/high-pass filter could separate the audio signal from the antenna signal. However, in this case, the filter should be tuned when moving across the frequency band in order to keep the antenna efficiency high. Using a switch enables a simpler and cheaper implementation.

This embodiment is particularly suited for an AM-radio receiver.

In particular for an AM-radio reception, wires of a headset may be used as a kind of a short whip antenna (electrical short antenna) belonging to an active antenna. It has to be noted that in contrast to this approach, a regular whip is normally kept free of obstacles. Using the whip in an active mode for AM-radio reception requires that the headset wires are connected to an active amplifier circuit, which has a high input impedance and a low capacitance input. The wires of the headset earspeakers are less suited to fulfill these requirements, as the audio amplifier and the electro-static discharge (ESD) circuit will load the antenna very hard. It is therefore proposed that a wire of a microphone is used as a short whip antenna for AM-band reception. When using the microphone wire as a high impedance whip antenna, the microphone should be disconnected inside the electronic device before entering the ESD protection circuit. Using the microphone input in combination with some kind of a switch will enable AM-radio reception with the whip concept alternately with the regular use of the microphone. Advantageously, the switch represents a low capacitance load relative to ground, in order to ensure that the capacitive load at the input of the active amplifier circuit is rather low. It has to be noted that the switching advantageously disconnects both balanced wires of the microphone.

The headset connector may be connected within the electronic device in addition to a frequency-modulation radio receiver in a conventional manner. This means that an analog FM-radio antenna can be reused for AM-band reception by adding an active amplifier circuit behind the FM-radio antenna.

In practice an FM-band antenna, for instance a headset cable, is not suitable for AM-band reception. But combining for example digital AM-band reception and an active AM-band circuit with a FM antenna leads to good results for digital AM band reception. The invention thus enables for instance the supplementary use of an existing passive antenna in an active antenna, without additional requirements that cannot be fulfilled in a sensible manner by mobile electronic devices from a technical or commercial perspective.

The invention is of particular advantage for small electronic devices, for instance for handheld devices, but it is to be understood that it may be employed with larger, stationary devices as well. The electronic device can be for instance a wireless communication device, like a mobile phone.

### BRIEF DESCRIPTION OF THE FIGURES

Other objects and features of the present invention will become apparent from the following detailed description considered in conjunction with the accompanying drawings.

FIG. 1 is a diagram illustrating different spheres above the Earth's surface;

FIG. 2 is a diagram illustrating short wave propagations;

FIG. 3 is a schematic block diagram of a conventional homodyne DRM receiver;

FIG. 4 is a diagram of a quarter-wave vertical antenna used in the receiver of FIG. 3;

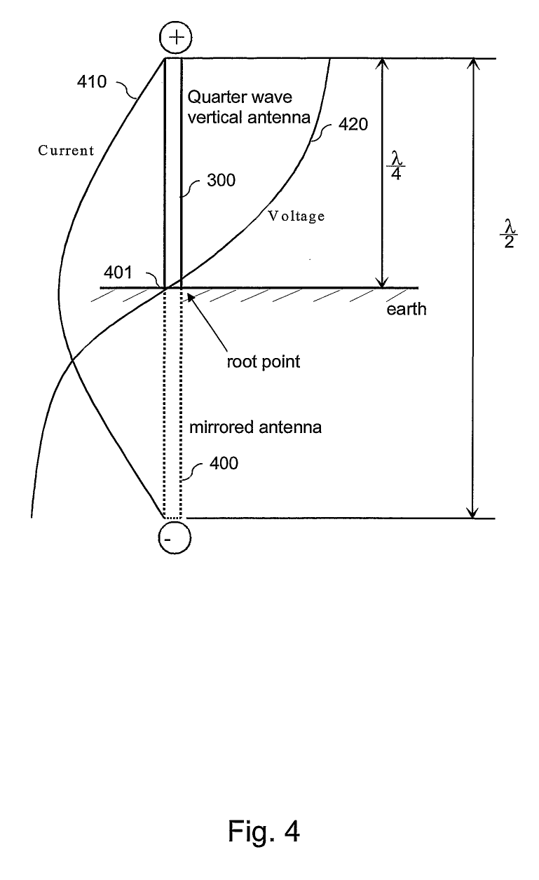

FIG. 5 is a schematic diagram of a system according to an embodiment of the invention;

FIG. 6 is a diagram illustrating some exemplary implementation details of the system of FIG. 5;

FIG. 7 is a diagram illustrating some further exemplary implementation details of the system of FIG. 5;

FIG. 8 is a flow chart illustrating an operation in the system of FIG. 5 implemented in accordance with FIGS. 6 and 7;

FIG. 9 is a diagram illustrating some alternative exemplary implementation details of the system of FIG. 5; and

FIG. 10 is a flow chart illustrating an operation in the system of FIG. 5 implemented in accordance with FIG. 9.

### DETAILED DESCRIPTION OF THE INVENTION

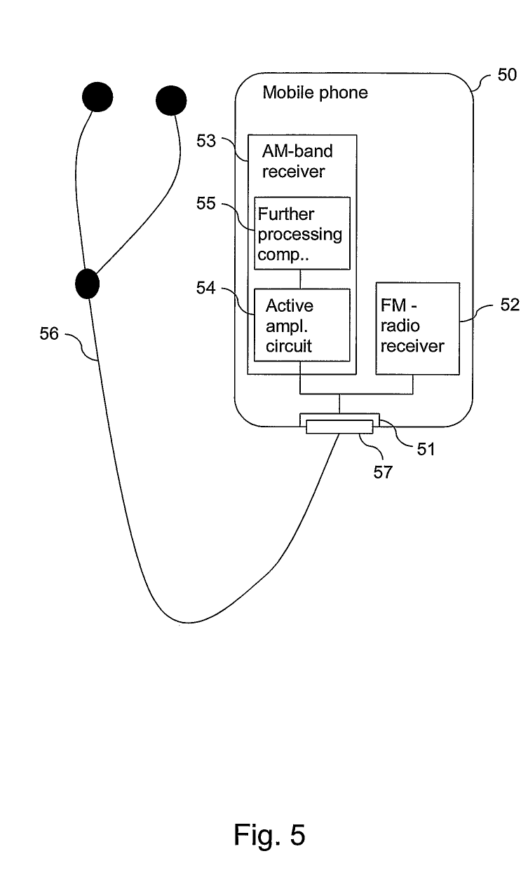

FIG. 5 is a schematic diagram of an exemplary embodiment of a system according to the invention, which enables an AM-band reception without a very long antenna.

The presented system comprises a mobile phone 50 and a headset 56. The mobile phone 50, which constitutes an exemplary electronic device according to the invention, includes a headset connector 51. Within the mobile phone 50, the headset connector 51 is not only connected to audio processing components (not shown), but also capacitively coupled to an FM-radio receiver 52 and to an AM-band receiver 53. The AM-band receiver 53 comprises an active amplifier circuit 54 and further processing components 55. The headset 56 can be connected by means of a corresponding connector 57 to the headset connector 51 of the mobile phone 50.

When a headset 56 is connected to the mobile phone 50, its cable may be used as an antenna for the FM-radio receiver 52 in a conventional way. Due to the active amplifier circuit 54 of the AM-band receiver 53, the cable of the headset 56 may also be used as an antenna for the AM-band receiver 53.

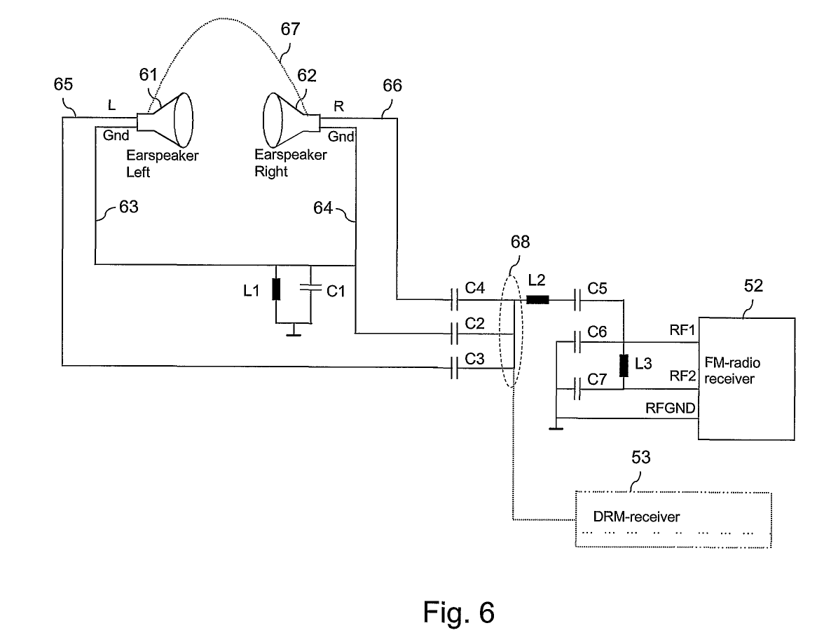

In one implementation, the AM-band receiver 53 of FIG. 5 may be a DRM receiver. FIG. 6 is a diagram presenting exemplary details of the mobile phone of FIG. 5 comprising such a DRM receiver 53. More specifically, FIG. 6 presents how the cable of the headset 56 may be connected via the connectors 51, 57 to the FM-radio receiver 52 and to the DRM receiver 53.

The headset 56 comprises a left earspeaker 61 and a right earspeaker 62, which may be physically coupled by a stirrup 67. A respective ground (Gnd) wire 63, 64 of both earspeakers 61, 62 is connected via the same parallel connection of an impedance L1 and a capacitor C1 to ground.

In addition, the ground wire 63, 64 of both earspeakers 61, 62 is connected via the same capacitor C2 to a common point 68. Moreover, a left (L) active wire 65 of the left earspeaker 61 and a right (R) active wire 66 of the right earspeaker 62 are connected via a respective capacitor C3, C4 to the common point 68.

The headset wires 63 to 66 may have a length of approximately one meter.

The common point 68 is connected via a series connection of an impedance L2 and a capacitor C5 to a first input RF1 of the FM-radio receiver 52, and via the series connection of impedance L2 and capacitor C5 and a further impedance L3 to a second input RF2 of the FM-radio receiver 52. The first input RF1 and the second input RF2 are connected via a respective capacitor C6, C7 to ground, while a ground input RFGND of the FM-radio receiver 52 is connected directly to ground. The FM antenna uses the headset wires 63 to 66 and is implemented as a conventional passive antenna.

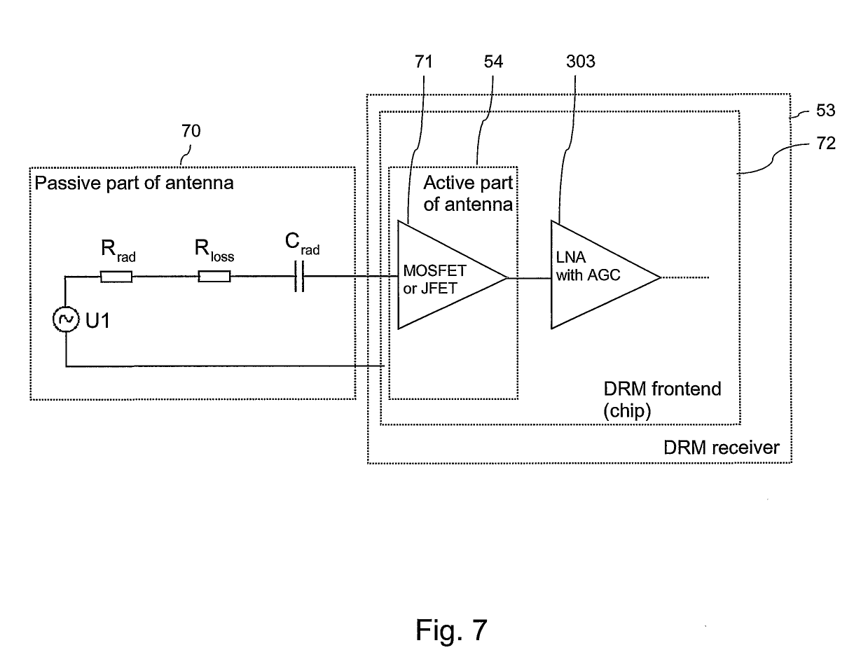

In the implementation of FIG. 6, the common point 68 is moreover connected to an input of a DRM receiver 53. The DRM antenna is implemented as an active antenna. An active antenna consists of a passive part and an active part, as illustrated in FIG. 7.

The passive part 70 of the active antenna is the actual antenna element, which corresponds in the present example to the headset wires 63 to 66. It can be represented by a voltage source U1 that is connected in series with an antenna resistor R_{rad}, a loss resistor Rₗₒₛₛ and an antenna capacitor C_{rad}. The voltage source U1 represents the signal level of a signal received via the antenna.

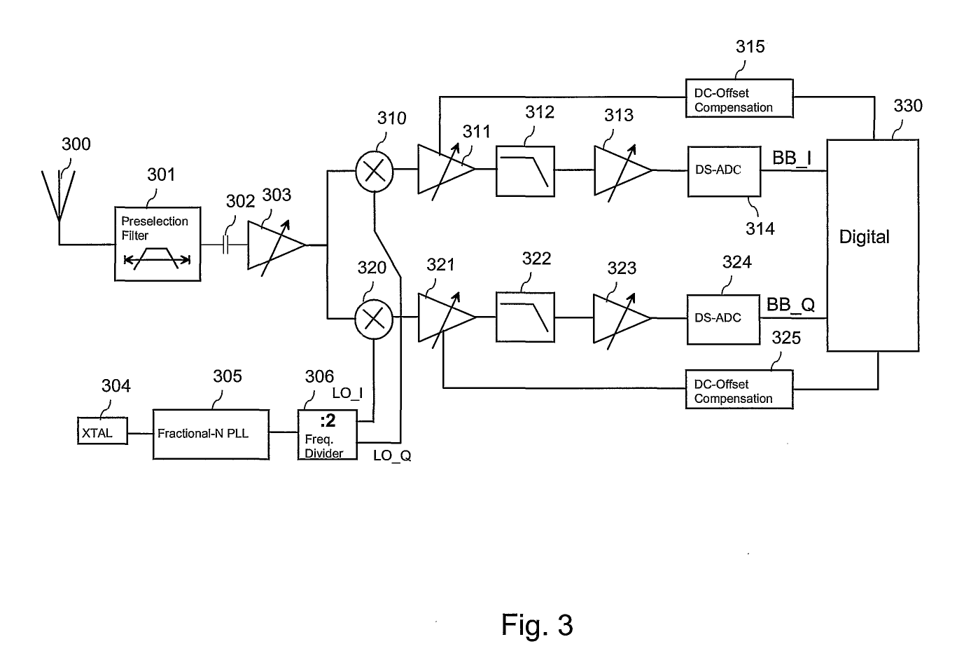

The active part of the active antenna corresponds to the active amplifier circuit 54 of the DRM receiver 53. The active amplifier circuit 54 may comprise for example simply an active amplifier 71, like a JFET or a MOSFET. The output of the JFET or MOSFET 71 is connected to further processing components 55. The further processing components 55 may comprise for instance an LNA 303 that is connected via an in-phase branch 310-315 and a quadrature branch 320-325 to a digital signal processor 330, as described above with reference to FIG. 3. Further processing components are provided in the DRM receiver 53 for converting the digital output of the digital signal processor 330 into analog audio signals in a conventional manner. The active part of the antenna 54 and the components 303 to 330, of which only LNA 303 is depicted in FIG. 7, belong to the DRM frontend of the DRM receiver and may be integrated on a single chip 72. Alternatively, for example, only the analog processing components of the DRM frontend 72 could be implemented on a single chip, while the digital processing components are provided on another chip.

The passive part of the antenna 70 is connected by AC-coupling with the input stage amplifier circuit realized by the FET 71, which provides a high-ohmic and low capacitive input-impedance and therefore does not reduce the antenna input signal level. The antenna capacitor C_{rad} together with the input capacitance is building up a capacitive voltage-divider. The lower the FET input stage capacitance, the more antenna signal voltage is fed into the analog front-end. A low input capacitance gives at the same time a very broadband response. The FET input noise has to be designed as low as possible, but there is a trade-off between input capacitance and noise behavior.

The active part of the antenna 54 is designed such that it provides a high linearity, even for large signals. As a result, less disturbances by cross-modulation and inter-modulation are caused. Further, the active part of the antenna 54 is designed such that it causes low noise. If the linearity capabilities of the active part of the antenna 54, of the LNA 303 or of the mixers 310, 320 in the analog frontend are not sufficient in the presence of strong interfering signals, in addition a frequency selective filtering may be provided, similarly as in FIG. 3. The preselection filter could be arranged at the input of the active part of the antenna 54.

These provisions ensure that the inter-modulation robustness is high, meaning the reception of the usually weak wanted signal is stable, even when there are strong interfering signals in the adjacent frequency bands.

The active antenna reception has to be broadband within the used frequency section, namely short wave (SW), middle wave (MW) or long wave (LW), as the propagation conditions vary over time, and therefore the transmitter frequency of the different channels can change quite often. The broadband reception has to be achieved in a mobile phone 50 with a supply voltage of only approximately 2.5 V. The requirements on the level of the voltage supply can reduced by using low noise input amplifiers, automatic gain control and filtering stages, in order to keep the signal level always in the linear region within the analog signal chain. Nevertheless, such a low supply voltage limits the achievable sensitivity and linearity properties of the active antenna. Still, the required SNR for a stable DRM reception is as low as 15 dB, such that an active vertical antenna of approximately one meter length is sufficient to receive the full frequency range from 10 kHz to 30 MHz.

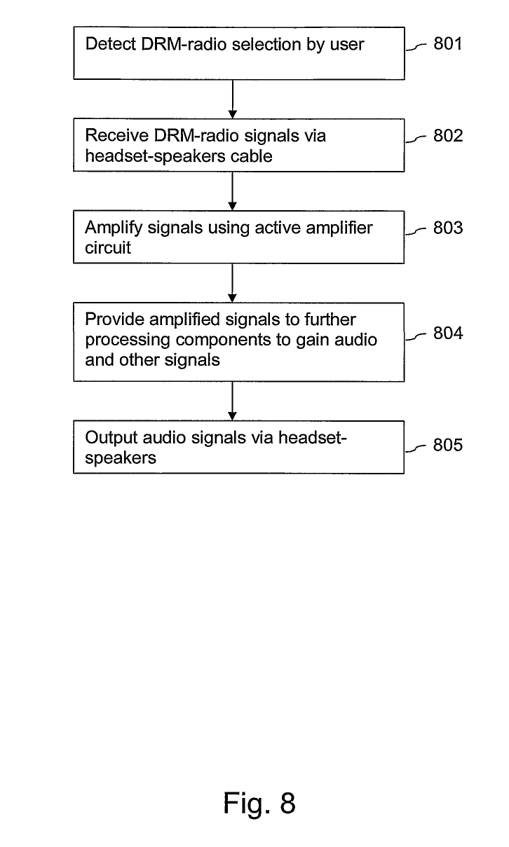

FIG. 8 is a flow chart illustrating the operation of a DRM reception by the mobile phone 50 of FIG. 5 that is implemented according to FIGS. 6 and 7.

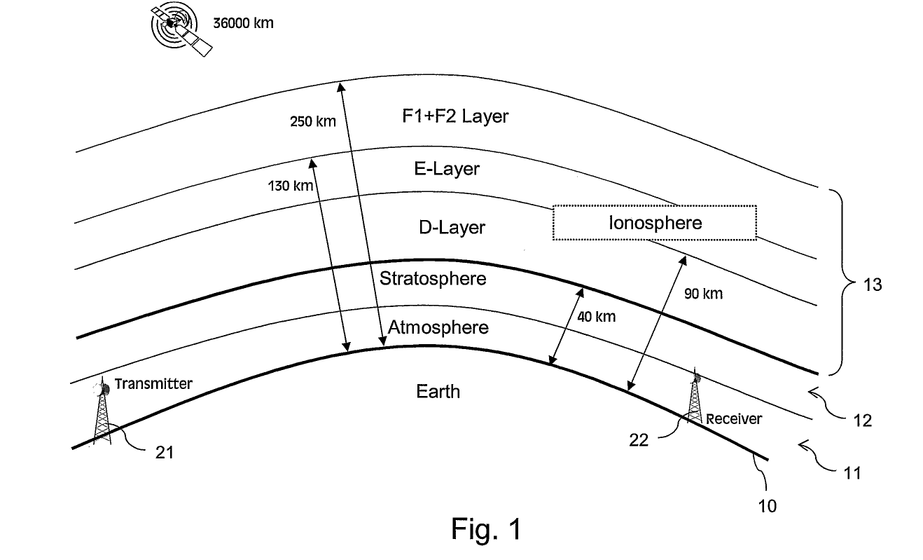

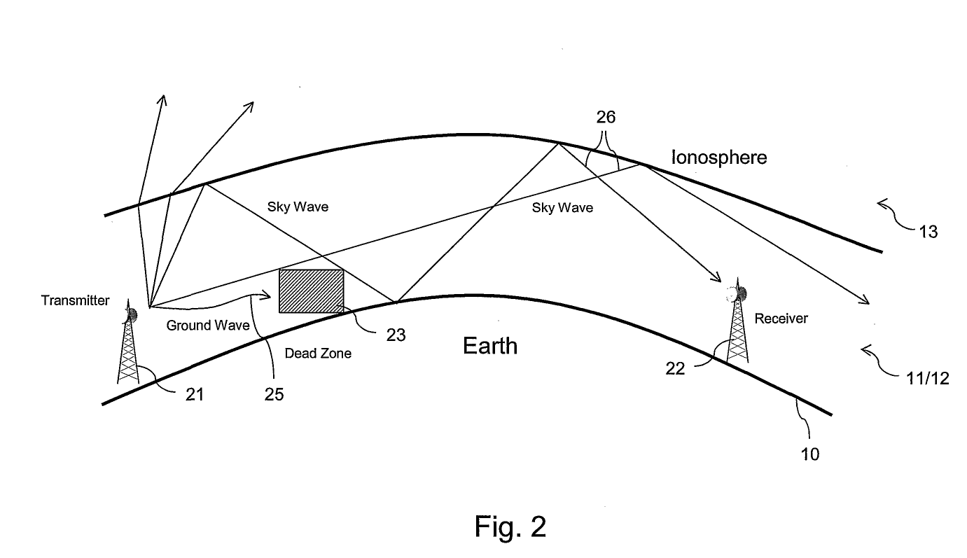

A DRM transmitter broadcasts DRM signals, which propagate as described above with reference to FIGS. 1 and 2.

If DRM reception is selected by a user of the mobile phone 50 (step 801), DRM signals are received via the earspeakers wires 63-66 of a connected headset 56 (step 802). The signals are amplified using an active amplifier circuit 54 (step 803), more specifically the MOSFET or JFET 71. The amplified signals are then provided to the LNA 303 etc. for further processing to gain audio signals and/or video signals in a conventional manner (step 804). The audio signals may then be output via the earspeakers 61, 62 of the headset 56 in a conventional manner (step 805).

The implementation according to FIGS. 5 and 6 thus provides an antenna proposal for Digital Radio Mondiale for mobile phones, where the FM headset antenna from analog FM radio can be fully reused for AM band reception.

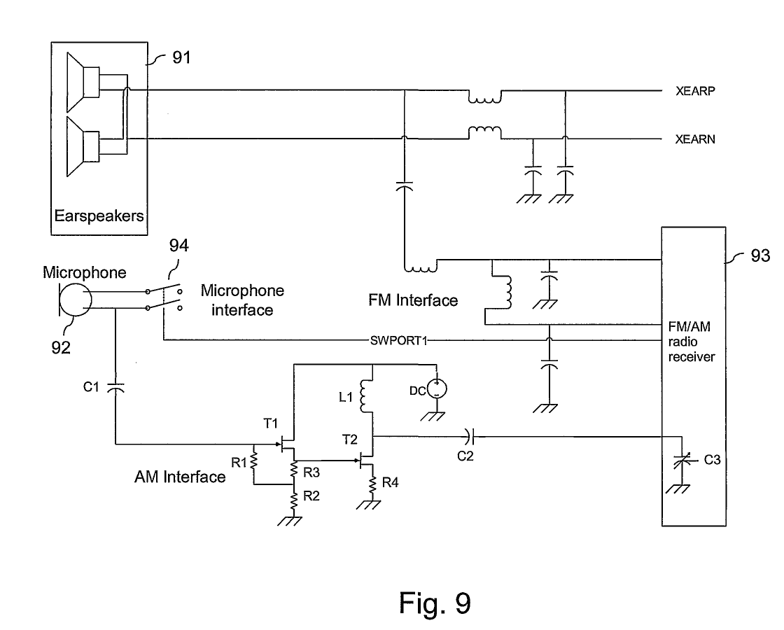

In another implementation of the mobile phone 50 of FIG. 5, the AM-band receiver 53 may be an AM-radio receiver. FIG. 9 is a diagram presenting exemplary details of the mobile phone of FIG. 5 comprising such an AM-radio receiver 53.

In FIG. 9, the earspeakers 91 and the microphone 92 of a headset 56 are depicted.

The earspeakers 91 are connected in a conventional manner to a respective audio signal source XEARP, XEARN and in addition via an FM interface to FM input ports of a combined FM/AM radio receiver 93. The wires of the earspeakers 91 are thus used by the FM/AM radio receiver 93 as a passive FM-band antenna.

The two, balanced wires of the microphone 92 of FIG. 9 can be connected by a switch 94 to a conventional microphone interface, or be disconnected by the switch 94 from this microphone interface. The switch 94 is controlled by a software output port SWPORT1 of the FM/AM-radio receiver 93.

The microphone 92 is further connected via an AM interface, comprising an active amplification circuit, to an AM input port of the FM/AM-radio receiver 93. One of the microphone wires is connected more specifically via a capacitor C1 to a gate of a first transistor T1 and via capacitor C1, a resistor R1 and a resistor R2 to ground. The source of the transistor T1 is connected via a resistor R3 and resistor R2 equally to ground. In addition, the source of transistor T1 is connected to the gate of second transistor T2. The source of transistor T2 is connected via a resistor R4 to ground. A voltage supply DC is connected between the drain of transistor T1 and ground and in parallel via an impedance L1 between the drain of transistor T2 and ground. The drain of transistor T2, finally, is connected via a capacitor C2 to the AM input of the FM/AM-radio receiver 93, and within the FM/AM-radio receiver 93 via a variable capacitor C3 to ground. In this example, the amplification circuit of the active antenna comprising transistors T1 and T2, resistors R1-R4 and impedance L1 thus realizes a two-stage amplification by means of transistors T1 and T2. It has a high input impedance and a low capacitance input.

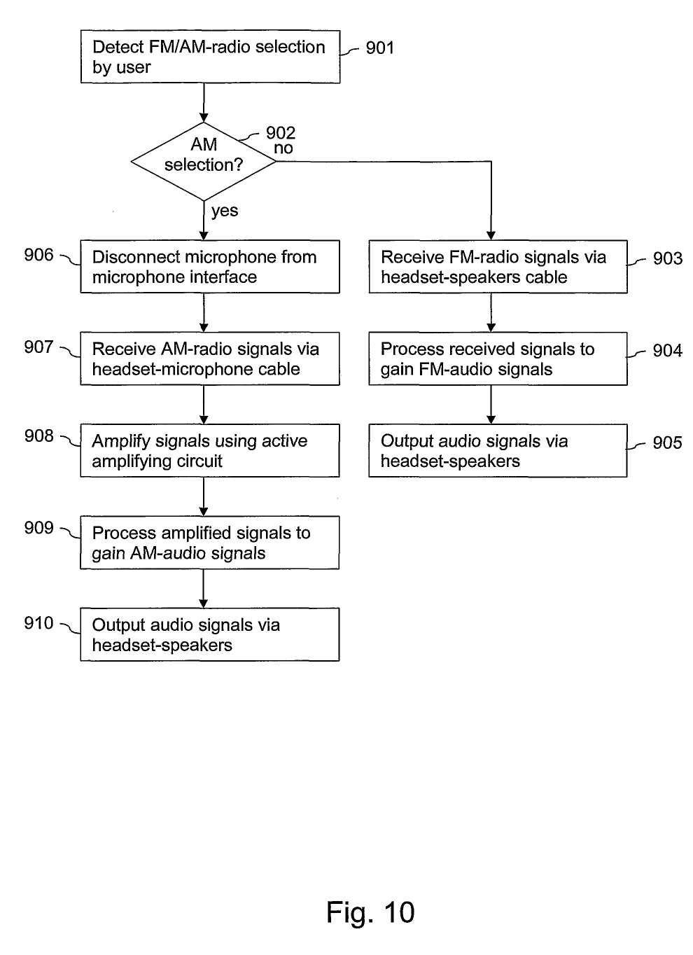

FIG. 10 is a flow chart illustrating the operation of the FM/AM-radio reception by the mobile phone 50 of FIG. 5 implemented according to FIG. 9.

If a radio reception is selected by a user while a headset 56 is connected to the mobile phone 50 (step 901), it is determined whether an AM-radio reception has been selected (step 902). Both can be determined e.g. by an appropriate software.

In case no AM-radio reception has been selected, and thus an FM-radio reception, the FM-band signals are received via the wires of the headset earspeakers 91 (step 903). The received signals are provided to the FM/AM-radio receiver via the FM interface and processed in a conventional manner for gaining FM audio signals (step 904). The gained audio signals are then output via the headset earspeakers (905).

In case AM reception has been selected (step 902), in contrast, the FM/AM-radio receiver 93 causes the switch 94 to disconnect both wires of the microphone 92 from the microphone interface (step 906). The switch control by the FM/AM-radio receiver 93 can be realized by a software modification in the radio software. The AM-band signals are then received via a wire of the headset microphone 92 and provided to the AM interface (step 907). The AM interface applies an active amplification using the active amplification circuit (step 908). The amplified signals are provided to the FM/AM-radio receiver for processing to gain AM audio signals (step 909). The gained AM audio signals are then output via the headset earspeakers 91 (step 910).

It has to be noted that in general, both the microphone or the earspeaker lines can be used for an AM and/or DRM receiver, but as the AM/DRM receiver may be an additional application in the electronic device then the cheapest solution would be separate wires for separate receivers. The AM/DRM antenna interface requires the high impedance/low capacitance input—which do not fit with FM receiver requirements, nor with the normal noise suppression components found in the audio lines—components which the FM radio antenna interface can accept. By using the microphone lines and a switching system, an AM/DRM receiver can be added as a “module” to an existing electronic device concept, for example an existing mobile phone concept.

It is to be noted that the described embodiments constitute only some of a variety of possible embodiments of the invention.

1. An electronic device comprising:
a headset connector adapted to connect a headset to said electronic device; and
an active amplifier circuit connected to said headset connector, said active amplifier circuit being adapted to amplify radio signals received by an antenna, which is connected to said electronic device via said headset connector.

2. The electronic device according to claim 1, wherein said active amplifier circuit comprises at least one of a Junction-Field-Effect-Transistor and a Metal-Oxide-Semiconductor-Field-Effect-Transistor.

3. The electronic device according to claim 1, further comprising at least one processing component for processing signals amplified by said active amplifier circuit.

4. The electronic device according to claim 3, wherein said at least one processing component belongs to a radio receiver of said electronic device, which radio receiver is adapted to process radio signals in a frequency range of 10 kHz to 30 MHz.

5. The electronic device according to claim 3, wherein said at least one processing component belongs to at least one of an amplitude-modulation radio receiver of said electronic device and a Digital Radio Mondiale radio receiver of said electronic device.

6. The electronic device according to claim 1, wherein said headset connector is adapted to connect a wire of at least one headset earspeaker to said active amplifier circuit, when a headset comprising at least one earspeaker is connected to said electronic device via said headset connector.

7. The electronic device according to claim 1, wherein said headset connector is adapted to connect a wire of a headset microphone to said active amplifier circuit, when a headset comprising a microphone is connected to said electronic device via said headset connector.

8. The electronic device according to claim 7, further comprising a microphone interface, which is connected to said headset connector, and a switch adapted to disconnect wires of a microphone of a headset from said microphone interface for receiving radio signals, when a headset comprising a microphone is connected to said electronic device via said headset connector.

9. The electronic device according to claim 1, further comprising a frequency-modulation radio receiver, wherein said headset connector is connected in addition to said frequency-modulation radio receiver.

10. The electronic device according to claim 1, wherein said electronic device is a wireless communication device.

11. A system comprising an electronic device according to claim 1 and an antenna connected to said electronic device via said headset connector of said electronic device.

12. The system according to claim 11, wherein said antenna is formed by at least one wire of a headset connected to said headset connector.

13. The system according to claim 11, wherein said antenna has a length between 0.5 and 1 meter.

14. An apparatus comprising:
an input enabling a connection to a headset connector of said electronic device inside of said electronic device; and
an active amplifier circuit connected to said input, said active amplifier circuit being adapted to amplify radio signals received by an antenna, which is connected to said electronic device via said headset connector.

15. A method comprising:
receiving at an electronic device radio signals via an antenna, which is connected to said electronic device via a headset connector of said electronic device; and
amplifying said received radio signals with an active amplifier circuit.

16. The apparatus according to claim 14, wherein said active amplifier circuit comprises at least one of a Junction-Field-Effect-Transistor and a Metal-Oxide-Semiconductor-Field-Effect-Transistor.

17. The apparatus according to claim 14, further comprising at least one processing component for processing signals amplified by said active amplifier circuit.

18. The apparatus according to claim 17, wherein said at least one processing component belongs to a radio receiver of said electronic device, which radio receiver is adapted to process radio signals in a frequency range of 10 kHz to 30 MHz.

19. The apparatus according to claim 17, wherein said at least one processing component belongs to at least one of an amplitude-modulation radio receiver of said electronic device and a Digital Radio Mondiale radio receiver of said electronic device.

20. The apparatus according to claim 14, comprising an interface adapted to connect a wire of at least one headset earspeaker to said active amplifier circuit, when a headset comprising at least one earspeaker is connected to said electronic device via said headset connector.

21. The apparatus according to claim 14, comprising an interface adapted to connect a wire of a headset microphone to said active amplifier circuit, when a headset comprising a microphone is connected to said electronic device via said headset connector.

22. The apparatus according to claim 21, further comprising a switch adapted to disconnect wires of a microphone of a headset from a microphone interface of said electronic device for receiving radio signals, when a headset comprising a microphone is connected to said electronic device via said headset connector.

23. The apparatus according to claim 14, further comprising a frequency-modulation radio receiver and an interface adapted to connect said headset connector to said frequency-modulation radio receiver.

24. The method according to claim 15, wherein said active amplifier circuit comprises at least one of a Junction-Field-Effect-Transistor and a Metal-Oxide-Semiconductor-Field-Effect-Transistor.

25. The method according to claim 15, further comprising processing signals amplified by said active amplifier circuit.

26. The method according to claim 25, wherein said processing comprises processing radio signals in a radio receiver in a frequency range of 10 kHz to 30 MHz.

27. The method according to claim 25, wherein said processing comprises processing radio signals in at least one of an amplitude-modulation radio receiver and a Digital Radio Mondiale radio receiver.

28. The method according to claim 15, comprising connecting a wire of at least one headset earspeaker to said active amplifier circuit by means of said headset connector, when a headset comprising at least one earspeaker is connected to said electronic device via said headset connector.

29. The method according to claim 15, comprising connecting a wire of a headset microphone to said active amplifier circuit by means of said headset connector, when a headset comprising a microphone is connected to said electronic device via said headset connector.

30. The method according to claim 29, further comprising disconnecting wires of a microphone of a headset from a microphone interface of said electronic device for receiving radio signals, when a headset comprising a microphone is connected to said electronic device via said headset connector.

31. The method according to claim 15, comprising providing signals that are received via said headset connector in addition to a frequency-modulation radio receiver of said electronic device.

32. The method according to claim 15, wherein said electronic device is a wireless communication device.
